(19) United States
(12) Patent Application Publication
(10) Pub. No.: US 2008/0211009 A1
(43) Pub. Date: Sep. 4, 2008

(54) Process for manufacturing an electronic device integrated on semiconductor substrate comprising non volatile floating gate memories and an associated circuitry and corresponding electronic device

(75) Inventors: Giorgio Servalli, Ciserano (IT); Daniela Brazzelli, Busto Arsizio (IT); Sonia Costantini, Monticello (IT); Alessia Pavan, Merate (IT)

Correspondence Address: GRAYBEAL, JACKSON, HALEY LLP, 155 - 108TH AVENUE NE, SUITE 350, BELLEVUE, WA, 98004-5973, US

(73) Assignee: STMICROELECTRONICS S.r.l., Agrate Brianza (IT)

(21) Appl. No.: 12/070,175

(22) Filed: Feb. 14, 2008

(30) Foreign Application Priority Data
Feb. 14, 2007 (IT) MI2007A 000270

(51) Int. Cl. H01L 27/115; H01L 21/8247

(52) U.S. Cl. 257/321; 438/128; 438/258; 257/E27.103; 257/E21.683

(57) ABSTRACT

An embodiment of a process is described for manufacturing a non volatile memory electronic device integrated on a semiconductor substrate which comprises a matrix of non volatile memory cells, the memory cells being organized in rows, called word lines, and columns, called bit lines and an associated circuitry comprising high voltage transistors and low voltage transistors, the process comprising the steps for realizing:
gate electrodes of the non volatile memory cells which comprise at least one first conductive layer, one first insulating layer, one second conductive layer and one third conductive layer and are insulated from the semiconductor substrate by means of a second insulating layer,
gate electrodes of high voltage transistors which comprise the at least one first conductive layer whereon the third polysilicon layer is overlapped and is insulated from the semiconductor substrate by means of a third insulating layer of greater thickness than the second insulating layer,
gate electrodes of low voltage transistors which comprise the second conductive layer whereon the third conductive layer is overlapped and are insulated from the semiconductor substrate by means of a fourth insulating layer.

### PRIORITY CLAIM

This application claims priority from Italian patent application No. MI2007A 000270, filed Feb. 14, 2007, which is incorporated herein by reference.

### TECHNICAL FIELD

An embodiment of the present invention relates to a process for manufacturing an electronic device integrated on a semiconductor substrate comprising floating gate non volatile memories and associated circuitry comprising high voltage transistors and low voltage transistors and to a corresponding electronic device.

An embodiment of the invention particularly, but not exclusively, relates to a process for manufacturing an electronic device integrated on a semiconductor substrate comprising non volatile memory cells of the floating gate type defined by means of self-aligned insulation of the STI type formed together with high performance CMOS transistors and the following description is made with reference to this field of application by way of illustration only.

### BACKGROUND

As it is well known, non volatile memory electronic devices, for example of the Flash type, integrated on a semiconductor substrate comprise a matrix of non volatile memory cells organized in rows, called word lines, and columns, called bit lines.

Each single non volatile memory cell comprises a MOS transistor wherein the gate electrode, arranged above the channel region, is floating, i.e. it has a D.C. high impedance towards all the other terminals of the same cell and of the circuit wherein the cell is inserted.

The cell also comprises a second electrode, called control gate, which is capacitively coupled to the floating gate electrode through an intermediate dielectric layer, so called interpoly. This second electrode is driven through suitable control voltages. The other electrodes of the transistor are the usual drain and source terminals.

The cells belonging to a same word line share the electric line which drives the respective control gates, while the cells belonging to a same bit line share the drain terminals.

Conventionally, memory electronic devices also comprise a control circuitry associated with the matrix of memory cells. The control circuitry comprises conventional high voltage MOS transistors each having a source region and a drain region separated by a channel region. A gate electrode is then formed over the channel region and insulated therefrom by means of a gate oxide layer.

It is also known that to define matrixes of high density floating gate non volatile cells, the floating gate electrodes of the cells are formed by means of insulation structures completely self-aligned thereto.

A process for manufacturing a memory electronic device of this type is described with reference to FIGS. 1 to 5. In particular, FIGS. 1 to 3 show vertical section views of a memory electronic device 100 of the known type in a direction parallel to that of the word lines of the matrix of memory cells, while FIGS. 4 and 5 show vertical section views in direction parallel to that of the bit lines of the matrix of memory cells.

In particular, with reference to these figures, a memory electronic device 100 is shown as formed on a silicon semiconductor substrate 101 and comprises a matrix of memory cells 102 formed in a first portion A1 of the semiconductor substrate 101 of the P type and high voltage MOS transistors 103 formed in a second portion B1 of the semiconductor substrate 101.

In the first portion A1 of the semiconductor substrate 101 there is a well 104 of the P type, wherein the memory cells 102 will be realized, delimitated by wells 105 of the N type.

In the second portion B1 of the semiconductor substrate 101 there are wells 106 of the P type, wherein high voltage MOS transistors 103 with n channel will be realized, and wells 107 of the N type, wherein high voltage MOS transistors 103 with p channel will be realized.

Buried regions 108 of the N type being below some of the wells of the P type, realize an insulation layer between said wells of the P type, conventionally called insulated P-wells, and the underlying semiconductor substrate 101.

On the semiconductor substrate 101 of the first portion A1 a first oxide layer 109, called a tunnel oxide, is then formed while on the semiconductor substrate 101 of the second portion B1, a second oxide layer 110 thicker than the first tunnel oxide layer 109, is formed.

On the whole memory electronic device 100 a first polysilicon layer 111, a third oxide layer 112 and a silicon nitride layer 113 are then formed in cascade as shown in FIG. 1.

In the first portion A1 of the semiconductor substrate 101 first trenches 114 are then realized while in the second portion B1 of the semiconductor substrate 101 second trenches 115 are realized, deeper than the first trenches.

Once a fourth conformal oxide layer 116 on the sidewalls of the first and second trenches 114 and 115 has been formed, these trenches 114 and 115 are filled in with an insulation oxide layer 117.

A CMP step (Chemical Mechanical Polishing) is then carried out until the nitride layer 113 is exposed, as shown in FIG. 2.

At the end of this process step active areas of the memory device 100 are then defined and delimited by insulation structures STI (Shallow Trench Isolation) formed by trenches 114 and 115 filled in by the insulation oxide layer 117. The active areas are covered by the tunnel oxide 109 and by a polysilicon layer which forms the floating gate of the memory cells; for the peculiar characteristics, this process flow for the formation of the insulation and of the floating gates of the memory cells is commonly called self-aligned STI.

Once also the nitride layer 113 and the third oxide layer 112 have been removed, on the whole memory electronic device 100 a second polysilico layer 118 is formed.

Once on the second polysilicon layer 118 a photolithographic mask provided with openings aligned with the first trenches 114 has been formed, this second polysilicon layer 118 is removed through the openings of the photolithographic mask to define electrodes of floating gate memory cells 102 along a direction parallel to the word lines of the matrix of memory cells 102.

On the whole memory device 100 a fifth layer 119 of conform oxide, as shown in FIG. 3 and then a third polysilicon layer 120 are formed.

The process for realizing the memory device 100 then provides a removal step in cascade of the third polysilicon layer 120, of the fifth conform oxide layer 119, of the second 118 and first polysilicon layer 111, through a further photolithographic mask, for completing the definition of the gate electrodes of the memory cells 102 along a direction parallel to the bit lines of the matrix of memory cells 102, as shown in FIG. 4.

In this step gate electrodes of the high voltage transistors 103 are also defined.

The source and drain regions of the memory cells 102 are then formed. Subsequently, the junctions of the high voltage transistors 103 are formed.

On the device 100, by using a photolithographic mask which covers the first portion A1, a removal step of the third polysilicon layer 120 and of the fifth conform oxide layer 119 is carried out for exposing the second polysilicon layer 118 to house the contacts to the gate electrodes of the high voltage transistors 103.

Once the photolithographic mask which covers the first portion A1 has been removed, a filler dielectric layer 121 is then formed and, by means of a photolithographic technique which uses a further photolithographic mask, the dielectric layer 121 is etched away for exposing the junctions of the memory cells and of the transistors, in the portions A1 and B1, so as to house the relative contacts.

The contacts 122 for the source/drain regions of the memory cells 102 and of the high voltage transistors 103, and the contacts 123 for the gate electrodes of the high voltage transistors 103 are then formed.

This manufacturing process, which provides the formation of insulation structures (trenches 114 and 117) self-aligned at least partially to the floating gate electrodes, allows the realization of high density electronic memory devices in a quite simple way and in general reduces the problems linked to the growth of the tunnel oxide layer 109 of good quality on portions of the substrate wherein insulation structures are already defined.

This manufacturing process, although advantageous for defining memory devices 100 comprising non volatile memory cells of the NAND type, down to the generation 70 nm, may a drawback in that it does not provide the integration of high performance low voltage LV CMOS transistors.

In fact the extension of this manufacturing process which provides insulation structures STI in non volatile memory devices needing high performance transistors (both standalone or embedded non volatile memories with NAND or NOR organization) is complicated by the peculiar insulation and definition scheme of the gate electrodes of the high performance low voltage (LV) transistors. In fact, the high performance CMOS LV transistors may require some characteristics that are different from the CMOS HV transistors previously described.

In particular these high performance CMOS LV transistors may require low thermal budgets for suitably controlling the channel length (generally short), may require thicknesses of the polysilicon layers upgraded with specific dopings of equivalent type to that of the channel of the transistors, and may require the formation of one gate oxide layer thinner than the CMOS HV transistors.

### SUMMARY

An embodiment of the present invention is a manufacturing process which allows one to integrate high performance CMOS LV transistors in memory devices comprising insulation structures of the self-aligned STI type, such as for example the one previously described, without jeopardizing the characteristics of the LV transistors and with a minimum number of masks for integrating the LV transistors.

An embodiment uses at least one double conductive layer for realizing the gate electrodes of the HV transistors and of the LV transistors integrated in a memory electronic device comprising non volatile memory cells.

An embodiment is a process for manufacturing non volatile memory electronic device integrated on a semiconductor substrate which comprises a matrix of non volatile memory cells, the memory cells being organized in rows, called word lines, and columns, called bit lines, and an associated circuitry comprising high voltage transistors and low voltage transistors comprising the steps for realizing: gate electrodes of the non volatile memory cells which comprise at least one first conductive layer, one first insulating layer, one second conductive layer and one third conductive layer and are insulated from the semiconductor substrate by means of a second insulating layer, gate electrodes of high voltage transistors which comprise at least the first conductive layer whereon the third polysilicon layer is overlapped and are insulated from the semiconductor substrate by means of a third insulating layer of lower thickness than the second insulating layer, gate electrodes of low voltage transistors which comprise the second conductive layer whereon the third conductive layer is overlapped and are insulated from the semiconductor substrate by means of a fourth insulating layer.

Features and advantages of the process and of the device according to one or more embodiment of the invention will be apparent from the following description of an embodiment thereof given by way of indicative and non limiting example with reference to the annexed drawings.

### BRIEF DESCRIPTION OF THE DRAWINGS

In these drawings:

FIGS. 1 to 5 respectively show schematic vertical section views of a portion of a memory electronic device during some known manufacturing steps,

FIG. 6 shows a schematic view from above of a portion of a memory electronic device realized according to an embodiment of the invention in which only the active areas are shown;

FIGS. 7 to 14 show schematic vertical section views along the line I-I of the memory electronic device of FIG. 5 during some manufacturing steps of an embodiment of the process,

FIG. 15 shows a schematic vertical section view along the line II-II of the memory electronic device of FIG. 5 during a manufacturing step of an embodiment of the process,

FIGS. 16 and 17 show schematic vertical section views along a line parallel to the line II-II of the memory electronic device of FIG. 5 during some manufacturing steps of an embodiment of the process,

FIGS. 18 to 24 show schematic vertical section views along the line I-I of the memory electronic device of FIG. 5 during some manufacturing steps of a further embodiment of the process,

FIG. 25 shows a schematic vertical section view along the line III-II of the memory electronic device of FIG. 5 during a manufacturing step of a further embodiment of the process,

FIGS. 26 and 27 show schematic vertical section views along a line parallel to the line II-II of the memory electronic device of FIG. 5 during some manufacturing steps of an embodiment of the process.

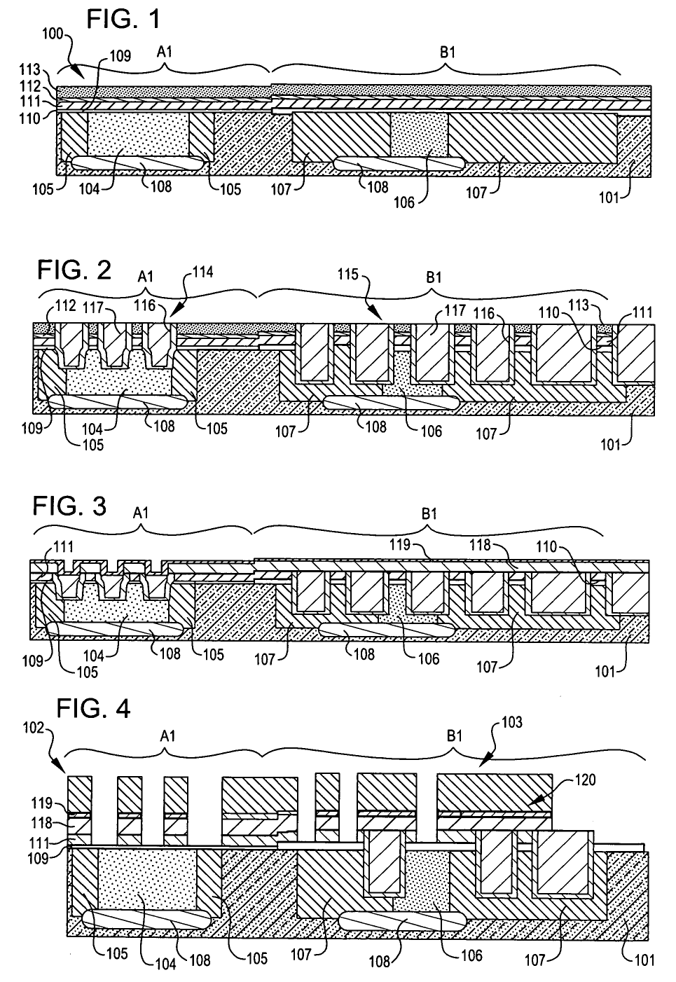

### DETAILED DESCRIPTION

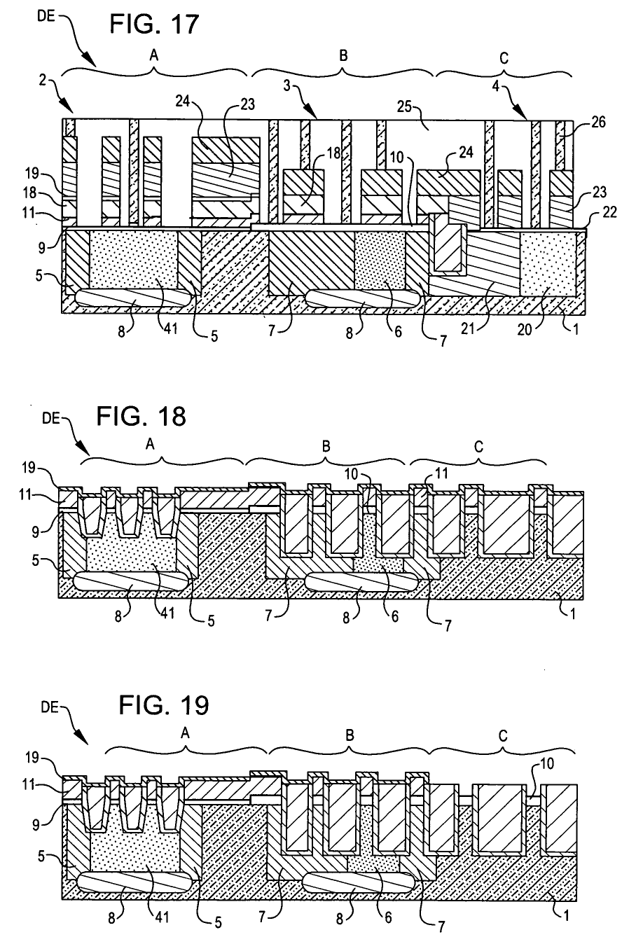

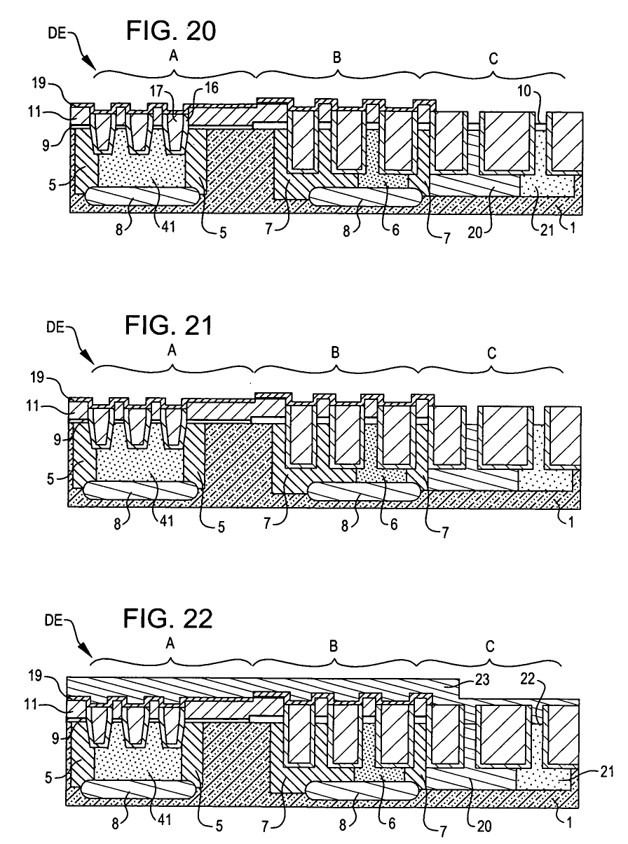

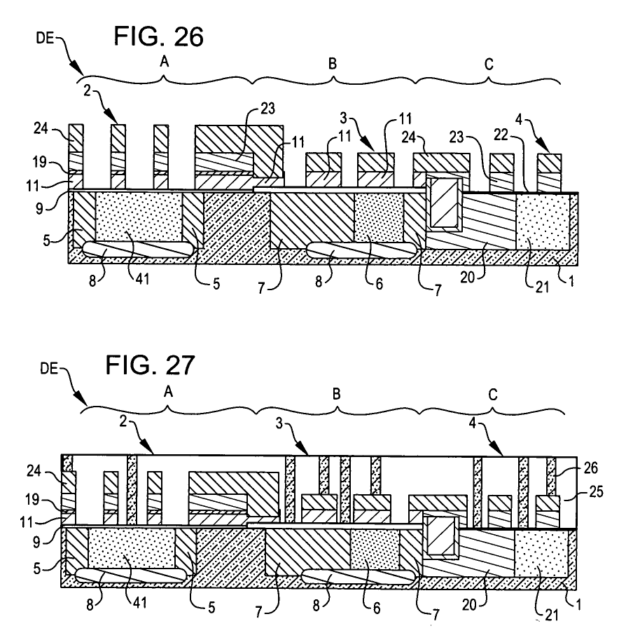

With reference to FIGS. 6 to 27, an embodiment of a non volatile memory electronic device DE is described.

The process steps and the structures described hereafter may not form a complete process flow for the manufacturing of integrated circuits.

The figures showing cross sections of portions of an integrated circuit during the manufacturing may not be drawn to scale, but instead may be drawn so as to show important features of one or more embodiment of the invention.

An embodiment of the present invention may be put into practice together with the manufacturing techniques of the integrated circuits currently used in the field, and only those commonly used process steps which may be necessary for the comprehension of one or more embodiment of the present invention are included.

In particular FIGS. 7 to 14 and 18 to 24 show vertical section views of a memory electronic device DE of the known type in a direction parallel to that of the word lines of the memory cell matrix, while FIGS. 15 to 17 and 25 to 27 show vertical section views in a direction parallel to that of the bit lines of the matrix of memory cells. The different vertical section views of the regions of the transistors of the CMOS logic show different portions of the structures for the realization of the transistors themselves (insulation structures, gate oxide layers, control gate electrodes, junctions and contacts).

In particular, with reference to FIGS. 7 to 17, a memory electronic device DE is shown formed on a substrate 1 which comprises a matrix of memory cells 2, organized in rows, called word lines, and columns, called bit lines, formed in a first portion A of the semiconductor substrate 1, and an associated circuitry comprising high voltage HV CMOS transistors 3 formed in a second portion B of the semiconductor substrate 1, for example of the P type, and low voltage LV CMOS transistors 4 formed in a third portion C of the semiconductor substrate 1.

The process according to an embodiment of the invention provides, at the beginning, the formation of wells of the P and N type in the first and in the second portion A, B of the semiconductor substrate 1, of active areas delimited by insulation structures in the three portions A, B, C of the semiconductor substrate 1, and the formation of two distinct insulation layers and at least one conductive layer on these active areas.

For example, in the first portion A of the semiconductor substrate 1 a well 41 of the P type is formed, wherein the memory cells 2 will be realized, delimited by wells 5 of the N type.

In the second portion B of the semiconductor substrate 1 wells 6 of the P type are formed, wherein high voltage transistors 3 with channel N will be realized, and wells 7 of the N type, wherein high voltage transistors 3 with channel P will be realized.

Advantageously, buried regions 8 of the N type which are present below some wells of the P type, realize an insulation layer between said wells of the P type, conventionally called insulated P-wells, and the underlying semiconductor substrate 1.

On the semiconductor substrate 1 of the first portion A a first insulating layer 9 is then formed, for example of a tunnel oxide called, while on the semiconductor substrate 1 of the second portion B and of the third portion C a second insulating layer 10 is then formed, for example of oxide, having a greater thickness than the first tunnel oxide layer 9.

On the whole semiconductor substrate 1, a first conductive layer 11, for example of polysilicon, a third insulating layer 12, for example of oxide and a protective layer 13, for example of silicon nitride, are then formed in sequence as shown in FIG. 7.

The first polysilicon layer 11 may have a thickness approximately between 30 nm and 50 nm (for example 40 nm).

In the first portion A of the semiconductor substrate 1, first trenches 14 are then realized while in the second portion B and in the third portion C of the semiconductor substrate 1 second trenches 15 are realized, deeper than the first trenches.

A fourth insulating layer 17 (sidewall oxide) having been formed on the walls of the first and second trenches 14 and 15, these trenches 14 and 15 are filled in with an insulation oxide layer 16 to form insulation structures of the STI type.

In the first portion A of the semiconductor substrate 1 first active areas insulated from each other by the first trenches 14 are then defined wherein the memory cells 2 covered by the first tunnel oxide layer 9 will be realized. These active areas are also covered by at least one portion of the floating gate electrodes of the cells formed by the polysilicon layer 11, while in the second and third portion B, C second active areas insulated from each other by the second trenches 15 are defined and are covered by the second oxide layer 10 and by the first conductive layer 11.

The first active areas have the form of stripes parallel to each other and extending substantially for the whole first portion A of the semiconductor substrate 1, while the second active areas have a substantially rectangular form, as shown in FIG. 6.

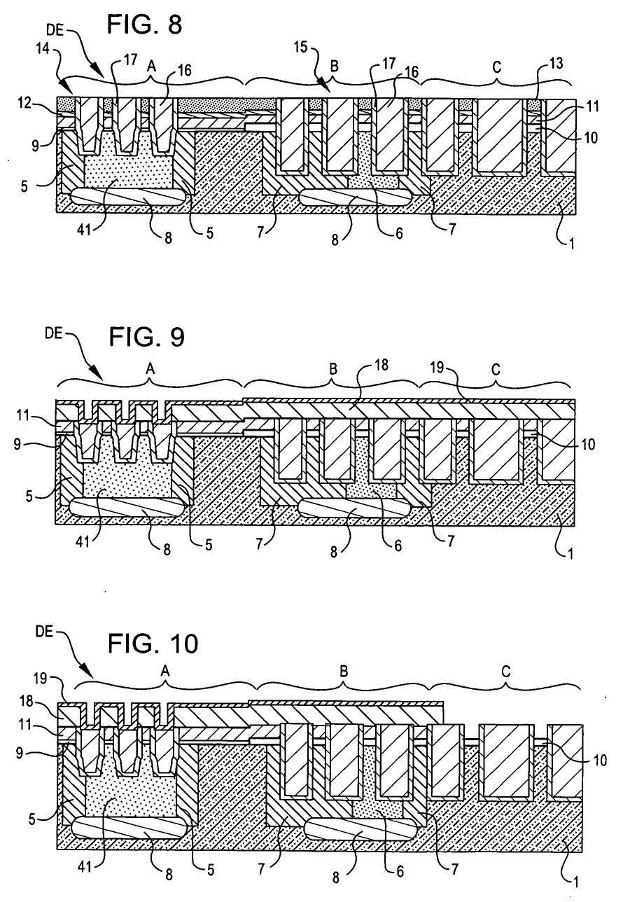

A planarizing step is then carried out through CMP (Chemical Mechanical Polishing) of the insulation oxide 17, until the nitride layer 13 is exposed, as shown in FIG. 8.

Once the nitride layer 13 and the third oxide layer 12 have been removed, on the whole memory electronic device DE a second conductive layer 18 is formed, for example of doped polysilicon of the N type.

This second polysilicon layer 18 may have a thickness approximately between 50 and 90 nm (for example 70 nm).

Once a photolithographic mask provided with openings positioned in correspondence with the first trenches 14 has been formed on the second polysilicon layer 18, this second polysilicon layer 18 is removed through the openings of the photolithographic mask for completing the floating gate electrodes of the memory cells 2 in a direction parallel to the word lines of the matrix of memory cells 2.

On the whole memory device DE a fifth insulating layer 19 is then formed, for example of conformal oxide, as shown in FIG. 9.

The fifth insulating layer 19 is an interpoly layer of ONO (Oxide-Nitride-Oxynitride).

According to an embodiment the invention, by means of a photolithographic technique which provides the use of a first photolithographic mask, the fifth oxide layer 19 and the second polysilicon layer 18 of the third portion C of the semiconductor substrate 1 are removed.

This first photolithographic mask does not require a critical alignment with the structures already formed on the semiconductor substrate 1.

In the third portion C of the semiconductor substrate 1 wells 20 of the P type are then realized, wherein low voltage transistors 4 with N channel will be realized, and wells 21 of the N type, wherein low voltage transistors 4 with P channel will be realized, as shown in FIG. 10.

The formation of these wells 20 and 21 is carried out through the help of a photolithographic technique which provides the use of two photolithographic masks.

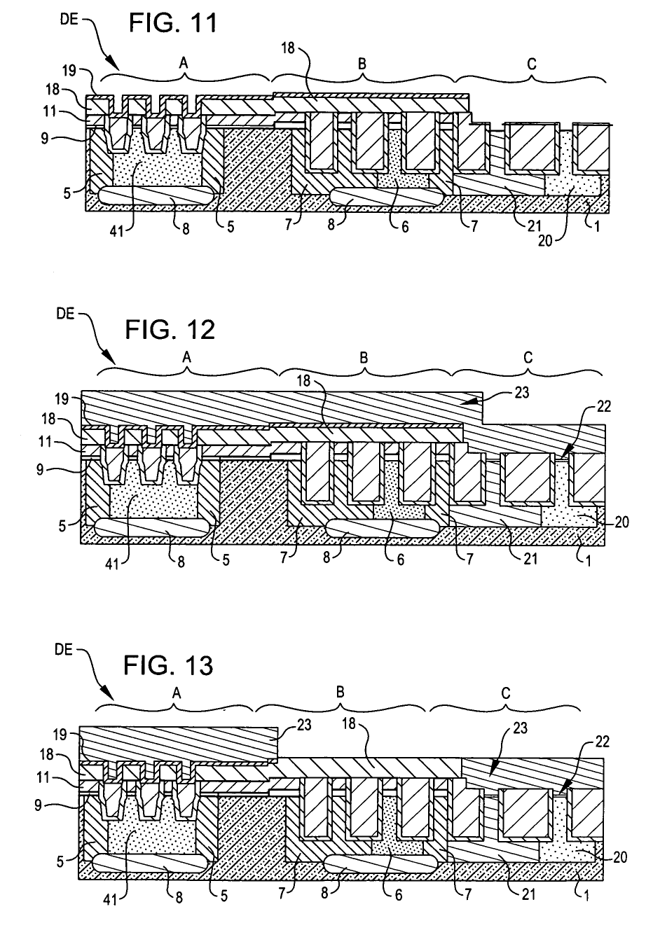

From this third portion C of the semiconductor substrate 1 the second oxide layer 10 is then removed, for exposing the semiconductor substrate 1, as shown in FIG. 11.

This removal step is carried out through the help of a photolithographic technique which provides the use of a photolithographic mask.

Nothing prevents this second oxide layer 10 from being removed prior to the formation of the wells 20 and 21.

A sixth insulating layer 22 is then formed, for example of oxide with lower thickness than the first oxide layer 9, on the semiconductor substrate 1 of the third portion C. Subsequently a third conductive layer 23 is formed, for example of polysilicon, on the whole memory electronic device DE, as shown in FIG. 12.

The sixth oxide layer 22 is obtained through thermal oxidation. This step does not affect the areas of the matrix and of the HV circuitry since these areas are covered by the fifth conformal oxide layer 19.

The third polysilicon layer 23 is of the undoped type, and it is of thickness approximately equal to the sum of the first layer 11 and of the second polysilicon layer 18, for example of about 110 nm. In other words the thickness of this third polysilicon layer 23 is approximately equal to that of all the other polysilicon layers formed in the second portion B of the semiconductor substrate 1.

As shown in FIG. 13, the third polysilicon layer 23 and the ONO layer 19 are removed from the second portion B of the semiconductor substrate 1, by means of a photolithographic technique which provides the use of a further photolithographic mask.

After this removal step, the surface of the second polysilicon layer 18 of the second portion B of the semiconductor substrate 1 is flush with the surface of the third polysilicon layer 23 of the third portion C of the semiconductor substrate 1.

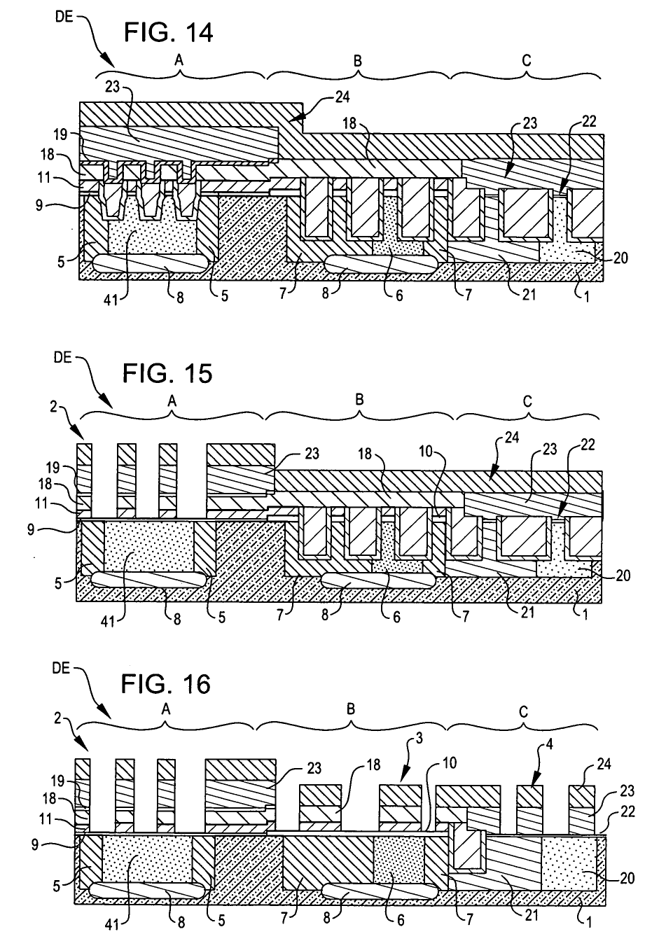

A fourth polysilicon layer 24 is formed on the whole electronic device DE, as shown in FIG. 14.

The fourth polysilicon layer 24 has such a thickness as to reach in the third portion C of the semiconductor substrate 1 the target requested for the thickness of the gate regions of the high performance low voltage transistors 4. For example the fourth polysilicon layer 24 has a thickness between approximately 30 and 50 nm, for example 40 nm, for reaching an overall thickness of the polysilicon layer in the third portion of the semiconductor substrate 1 of approximately 150 nm.

At the end of this process step on the semiconductor substrate 1 the following structures will be formed:

in the first portion A, above the active areas, a stack is formed comprising the first tunnel oxide layer 9, the first polysilicon layer 11 whereon the second n doped polysilicon layer 18 is overlapped for an overall thickness for example of approximately 110 nm, the layer 19 of ONO and the third polysilicon layer 23 whereon the fourth polysilicon layer 24 is overlapped for an overall thickness for example of approximately 150 nm,

in the second portion B, above the active areas, a stack is formed comprising the second HV oxide layer 10 and the first polysilicon layer 11 whereon the second N doped polysilicon layer 18 and the fourth undoped polysilicon layer 24 are overlapped for an overall thickness for example of approximately 150 nm,

in the third portion C, above the active areas, a stack is formed comprising the sixth LV oxide layer 22 and the third layer 23 whereon the fourth undoped polysilicon layer 24 is overlapped for an overall thickness for example of approximately 150 nm.

After the formation of the fourth polysilicon layer 24 a predoping step of this layer 24 can be carried out in the third portion C through the help of one or two additional photolithographic masks.

The process for manufacturing the memory device DE then provides a removal step in cascade of the fourth layer 24 and of the third polysilicon layer 23, of the fifth conformal oxide layer 19, of the second layer 18 and first polysilicon layer 11, through a photolithographic mask, for completing the definition of gate electrodes of the memory cells 2 along a direction parallel to the bit lines of the matrix of memory cells 2, as shown in FIG. 15.

Ionic implants are then carried out for realizing the source and drain regions of the memory cells 2.

Once this latter mask has been removed, through the help of a photolithographic technique which provides the use of a further photolithographic technique, a removal step is carried out of the stacks in the second B and third portions C of the semiconductor substrate 1 to define gate electrodes of the transistors 3 and 4.

These latter stacks, although being formed by layers realized by different process steps, have in fact approximately the same thickness and the same composition.

A first implantation step is then carried out with ions of the P type for doping the third and fourth polysilicon layers 23 and 24 in correspondence with the well 21 of the N type and a second implantation step with ions of the N type for doping the third and fourth polysilicon layers 23 and 24 in correspondence with the well 20 of the P type.

During these two implantation steps, source and drain regions of the circuitry, aligned to the gate electrodes, are formed.

An embodiment of the process then provides the definition of the spacers, for the integration of salicide layers that may be used for the high performance logic. This integration also comprises further implantation steps of the junctions of the transistors, with implants aligned to the spacers.

After the deposition of a premetal dielectric layer 25, contacts 26 are then formed directly on the fourth polysilicon layer 24 which is short-circuited with the underlying polysilicon layers 18 and 23.

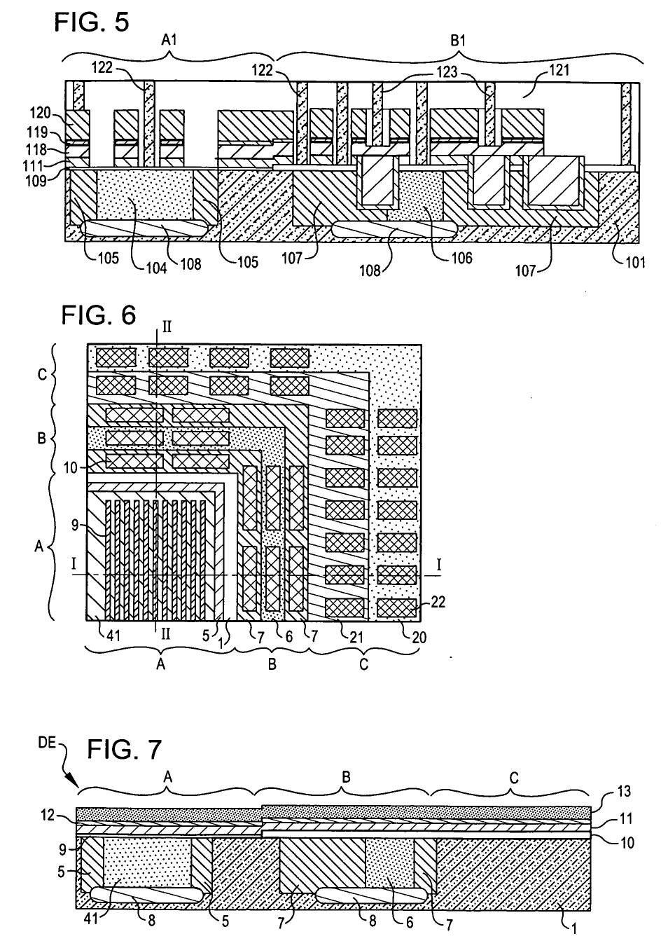

In the process according to an embodiment of the invention, the contact 26 to the gate electrodes of the HV transistors 3 HV is realized by opening openings in the premetal dielectric layer 25 which expose the polysilicon layer 24, without the need of removing polysilicon and oxide layers by using a dedicated photolithographic mask whose alignment to the underlying structures is critical, as instead may occur in the known process flow described with reference to FIG. 5.

According to an embodiment of the invention, by avoiding the use of this mask it may be possible to define more compact layout rules, considering additional tolerances for contacts and the first metallization layer forming the contacts 26 being not necessary.

The process is finally completed with conventional manufacturing steps of integrated circuits subsequent to the formation of the first metallization layer.

The process according to an embodiment the invention, allows one to integrate, without compromises, high performance CMOS LV logic in an insulation scheme of the STI type which provides the formation of the HV oxide and of the tunnel oxide prior to the definition of the insulation.

The use of shortcircuited polysilicon layers overlapped onto each other and the suitable choice of the thicknesses of these polysilicon layers also may allow one to realize this integration without the critical etching mask for the contacting of the circuitry gate electrodes as instead may occur in the prior art process, allowing more compact layout rules for the circuitry.

Although the process according to an embodiment the invention has been described with reference to floating gate electrodes of the memory cell 2 and to a portion of gate electrodes of the HV transistors 3 formed by a double polysilicon layer 11 and 18, this process may be also applied to the case in which the floating gate electrodes of the memory cells 2 are formed by the sole polysilicon layer 11 (completely self-aligned floating gate electrodes) as shown with reference to FIGS. 18 to 27.

Elements being structurally and functionally similar with respect to the process described with reference to FIGS. 7 to 17 will be given the same reference numbers.

In particular, in this alternative embodiment of the process, the formation of the wells N and P, and of the first and second trenches 14 and 15 until their planarization step occurs with the same modes indicated with reference to FIGS. 7 and 8.

In the alternative embodiment the first conductive layer 11 has a thickness between approximately 50 and 100 nm (for example 80 nm).

As shown in FIG. 18, the nitride layer 13 and the third oxide layer 12 are removed from the whole memory electronic device DE.

The insulating layers 16 and 17 are also superficially removed so that portions of the polysilicon conductive layer 11 project with respect to these insulating layers 16 and 17.

In particular, these portions of the polysilicon layer 11 form the floating gate electrodes of the memory cells 2 and first portions of the gate electrodes of the high voltage transistor 3.

On the whole memory device DE a fifth insulating layer 19 is then formed, for example of conformal oxide.

The fifth insulating layer 19 is an interpoly layer of ONO (Oxide-Nitride-Oxynitride).

By means of a photolithographic technique which provides the use of a first photolithographic mask, the fifth oxide layer 19 is removed from the third portion C of the semiconductor substrate 1.

This first photolithographic mask does not require a critical alignment with the structures already formed on the semiconductor substrate 1.

In the third portion C of the semiconductor substrate 1 wells 20 of the P type will be then realized, wherein low voltage transistors 4 with N channel will be realized, and wells 21 of the N type, wherein low voltage transistors 4 with P channel will be realized, as shown in FIG. 20.

The formation of these wells 20 and 21 is carried out through the help of a photolithographic technique which provides the use of two photolithographic masks.

From this third portion C of the semiconductor substrate 1 the second oxide layer 10 is then removed, for exposing the semiconductor substrate 1, as shown in FIG. 21.

This removal step is carried out through the help of a photolithographic technique which provides the use of a photolithographic mask.

A sixth insulating layer 22 is then formed, for example of oxide, for example of lower thickness than the first oxide layer 9 on the semiconductor substrate 1 of the third portion C. Subsequently a third conductive layer 23 is formed, for example of polysilicon, on the whole memory electronic device DE, as shown in FIG. 22.

The sixth oxide layer 22 is obtained through thermal oxidation. This step does not affect the matrix and HV circuitry areas since these areas are covered by the fifth conform oxide layer 19.

The third polysilicon layer 23 is of the undoped type, and it is of thickness approximately equal to that of the first layer 11, for example of about 80 nm. In other words the thickness of this third polysilicon layer 23 is approximately equal to that of the polysilicon formed in the second portion B of the semiconductor substrate 1.

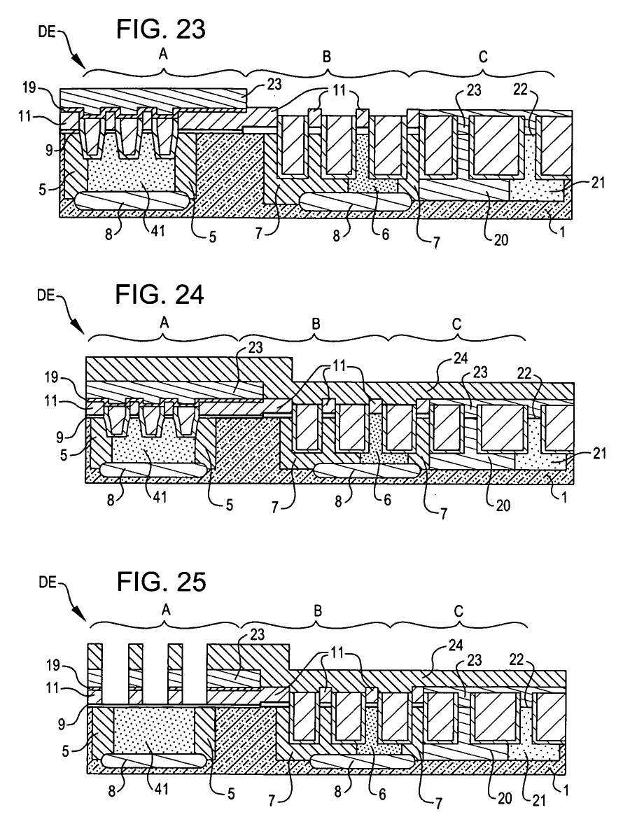

As shown in FIG. 23, the third polysilicon layer 23 is removed from the second portion B of the semiconductor substrate 1, by means of a photolithographic technique which provides the use of a further photolithographic mask.

After this removal step, the surface of the first polysilicon layer 11 of the second portion B of the semiconductor substrate 1 is approximately flush with the surface of the third polysilicon layer 23 of the third portion C of the semiconductor substrate 1.

A fourth polysilicon layer 24 is formed on the whole electronic device DE, as shown in FIG. 24.

The fourth polysilicon layer 24 has such a thickness as to reach in the third portion C of the semiconductor substrate 1 the target requested for the thickness of the gate regions of the high performance low voltage transistors 4. For example the fourth polysilicon layer 24 has a thickness approximately between 60 and 80 nm, for example 70 nm, for reaching an overall thickness of the polysilicon layer in the third portion of the semiconductor substrate 1 of 150 nm.

At the end of this process step on the semiconductor substrate 1 the following structures are formed:

in the first portion A, above the active areas, a stack is formed comprising the first tunnel oxide layer 9, the first polysilicon layer 11, the layer 19 of ONO and the third polysilicon layer 23 whereon the fourth polysilicon layer 24 is overlapped for an overall thickness for example of approximately 150 nm,

in the second portion B, above the active areas, a stack is formed comprising the second HV oxide layer 10 and the first polysilicon layer 11 whereon the fourth undoped polysilicon layer 24 is overlapped for an overall thickness for example of approximately 150 nm,

in the third portion C, above the active areas, a stack is formed comprising the sixth LV oxide layer 22 and the third layer 23 whereon the fourth polysilicon non doped layer 24 is overlapped for an overall thickness for example of approximately 150 nm.

After the formation of the fourth polysilicon layer 24 a predoping step of this layer 24 in the third portion C may be carried out through the help of one or two additional photographic masks.

The process for manufacturing the memory device DE then provides a removal step in cascade of the fourth layer 24 and of the third polysilicon layer 23, of the fifth conformal oxide layer 19 and of the polysilicon layer 11, through a photolithographic mask, for completing the definition of gate electrodes of the memory cells 2 along a direction parallel to the bit lines of the matrix of memory cells 2, as shown in FIG. 25.

Ionic implants are then carried out for realizing the source and drain regions of the memory cells 2.

Once this latter mask has been removed, through the help of a photolithographic technique which provides the use of a further photolithographic mask, a selective removal step of the stacks present in the second B and third portions C of the semiconductor substrate 1 is carried out to define gate electrodes of the transistors 3 and 4.

These latter stacks, although being formed by layers realized by different process steps, have in fact approximately the same thickness and the same composition.

A first implantation step is then carried out with ions of the P type for doping the third and fourth polysilicon layers 23, 24 in correspondence with the well 21 of the N type and a second implantation step with ions of the N type for doping the third and fourth polysilicon layers 23, 24 in correspondence with the well 20 of the P type.

During these two implantation steps source and drain regions of the circuitry are formed, aligned to the gate electrodes.

The process then provides the definition of the spacers, for the integration of salicide layers that may be used for the high performance logic. This integration also provides further implantation steps of the junctions of the transistors, with implants aligned to the spacers.

After the deposition of a premetal dielectric layer 25, contacts 26 are then directly formed on the fourth polysilicon layer 24 which is short-circuited with the underlying polysilicon layers 11 and 23.

The process is finally completed with the conventional steps for manufacturing the integrated circuits subsequent to the formation of the first metallization layer.

In particular, besides advantages that may be obtained with the previous embodiment, with this alternative embodiment it may also be possible to improve the growth characteristics of the HV oxide 10 and tunnel oxide 9 layers, whose oxidation steps occur on a substantially flat semiconductor layer and then they are at the same time ideal from the point of view of uniformity and limit the strains on the substrate, a potential cause of crystalline faultiness.

In particular, with the process according to an embodiment of the invention it is possible to realize a non volatile memory electronic device DE integrated on a semiconductor substrate 1 which comprises a matrix of non volatile memory cells 2, wherein the memory cells 2 are organized in rows, called word lines, and columns, called bit lines and an associated circuitry comprising high voltage transistors 3 and low voltage transistors 4, wherein the non volatile memory cells 2, said high voltage transistors 3 and low voltage transistors 4 are integrated in respective active areas delimited from each other by self-aligned insulation structures STI 14 and 15, and wherein:

gate electrodes of the non volatile memory cells 2 comprise at least one first conductive layer 11 and/or 18, one first insulating layer 19, one second conductive layer 23 and one third conductive layer 24 and are insulated from the semiconductor substrate 1 by means of a second insulating layer 9,

gate electrodes of high voltage transistors 3 comprise at least the first conductive layer 11 and/or 18 whereon the third polysilicon layer 24 is overlapped and are insulated from the semiconductor substrate 1 by means of a third insulating layer 10 of greater thickness than the second insulating layer 9,

gate electrodes of low voltage transistors 4 comprise the second conductive layer 23 whereon said third conductive layer 24 is overlapped and are insulated from the semiconductor substrate 1 by means of a fourth insulating layer 22.

The second conductive layer 23 may have a thickness equal to that of the at least one first conductive layer 11 and 18.

The fourth insulating layer 22 may be of lower thickness than the second insulating layer 9.

The at least one first conductive layer 11 and 18 may comprise a first conductive layer 11 and a fourth conductive layer 18.

The second conductive layer 23 has a thickness approximately equal to the sum of the thicknesses of said first and fourth conductive layer 11 and 18.

The gate electrodes of transistors 4 with N channel may have a doping of the N type and the gate electrodes of transistors 4 with P channel may have a doping of the P type.

In conclusion, the process according to an embodiment of the invention allows one to integrate high performance LV logic in an insulation scheme of the STI type, so that the last polysilicon layer 24 is short-circuited with the underlying polysilicon layers 11/18 and 23 in the different portions of the device DE.

Two alternative embodiments of the process flow may be particularly advantageous for manufacturing non volatile memories needing the integration with high performance LV transistors wherein the active areas of the memory cells and of the HV transistors are defined with a self-aligned insulation process of the STI type. In fact the deposition on the LV circuitry of a polysilicon layer 23 of thickness approximately equal to the polysilicon layer 11 or 11/18, i.e. of a thickness approximately equal to the thickness of the layer/s already on the HV circuitry, and the completion of the process with a further polysilicon layer 24 serving as wordline for the matrix and being short-circuited with the layers already in the circuitry may be advantageously applied in case the HV circuitry is already predefined (wells 7 and 8, HV gate oxide layer 10 and polysilicon layer 11/18).

Moreover, a process according to an embodiment of the invention allows one to solve the integration problems of both the HV transistors and the LV ones:

the wells 20 and 21 wherein the LV transistors 4 are realized are defined after the formation of the tunnel oxide layer 9 and of the HV gate oxide layer 10 and then these wells are not deteriorated by the thermal processes used for realizing these layers 9 and 10. In this way it may be possible to realize LV transistors 4 with a very short channel;

the oxide layer 22 of the LV transistors 4 is formed after the formation of the layers which define the floating gate electrodes allowing a great control of the thickness and of the quality of this layer;

moreover the gate electrodes of the LV transistors 4 LV are formed by polysilicon layers which may be suitably doped (with doping of the N type for the transistors with N channel and of the P type for the transistors with P channel) allowing the formation of high performance transistors, differently from the HV transistors 3, for which the gate electrodes may have doping of the N type both for transistors with N channel and for the transistors with P channel, the gate electrode of said HV transistors being formed by the same polysilicon layer 11 and/or 18 which forms the floating gate electrodes of the memory cells 2.

Moreover, the process here described may be advantageously applied to memories of the EPROM, EEPROM and Flash EEPROM type with NAND or NOR organization single level or multilevel with particular attention to the embedded memories.

At the morphologic level the devices realized with the process according to an embodiment of the invention may be easily recognized observing the characteristics of the different polysilicon layers deposited in short-circuit.

An integrated circuit (IC) formed according to an embodiment of the above-described process may be coupled to another IC, such as a controller, to form an electronic system.

From the foregoing it will be appreciated that, although specific embodiments of the invention have been described herein for purposes of illustration, various modifications may be made without deviating from the spirit and scope of the invention.

What is claimed is:

1. Process for manufacturing a non volatile memory electronic device integrated on a semiconductor substrate which comprises a matrix of non volatile memory cells, called memory cells organized in rows, called word lines, and columns, called bit lines, which are formed in a first portion of said semiconductor substrate and an associated circuitry comprising high voltage transistors formed in a second portion of said semiconductor substrate and low voltage transistors formed in a third portion of said semiconductor substrate, the process comprising the steps of:
forming first active areas delimited by self-aligned insulation structures STI and covered by a first insulating layer and by at least one first conductive layer in said first portion of said semiconductor substrate,
forming second active areas delimited by self-aligned insulation structures STI and covered by a second insulation layer and by said at least one first conductive layer both in said second and third portions of said semiconductor substrate,
forming a third insulating layer on said whole semiconductor substrate,
removing said third insulating layer, said at least one first conductive layer and said second insulating layer until said semiconductor substrate is exposed from said third portion of said semiconductor substrate,
forming wells of the N and P type and a fourth insulating layer in said third portion of said semiconductor substrate,
forming a second conductive layer on said whole semiconductor substrate,
removing said second conductive layer and said third insulating layer from said second portion of said semiconductor substrate,
depositing a third conductive layer on said whole semiconductor substrate,
forming gate electrodes of said memory cells, by selectively removing at least said third and second conductive layer, the third insulating layer and said at least one first conductive layer,
forming gate electrodes of the circuitry, by selectively removing at least said third conductive layer and simultaneously said second conductive layer and said at least one first conductive layer.

2. Process according to claim 1, wherein said second conductive layer has a thickness equal to that of said at least one first conductive layer.

3. Process according to claim 1, wherein said at least one first conductive layer is formed by a first conductive layer and a fourth conductive layer.

4. Process according to claim 1, wherein an ionic implantation step of the N type is carried out on said third and fourth conductive layers in correspondence with said wells of the P type of said third portion of said semiconductor substrate.

5. Process according to claim 1, wherein an ionic implantation step of the P type is carried out on said third and second conductive layers in correspondence with said wells of the N type of said third portion of said semiconductor substrate.

6. Process according to claim 1, wherein said fourth insulating layer is formed with a lower thickness than said first insulating layer.

7. Process according to claim 1 wherein said conductive layers are formed by polysilicon layers.

8. Process according to claim 1, wherein said insulating layers are formed by silicon oxide layers.

9. Process according to claim 1, wherein the formation of said first and second active areas comprises the steps of:
forming said first insulating layer of a first thickness in said first portion of said semiconductor substrate,
forming said second insulating layer of a second thickness greater than the first thickness in said second and third portion of said semiconductor substrate,
forming in cascade, on said whole semiconductor substrate said first conductive layer and at least one protective layer,
forming first trenches in said first portion of said semiconductor substrate by selectively removing, in cascade, said at least one protective layer, said first conductive layer, said first insulating layer and said semiconductor substrate, for delimiting said first active areas,
in said second and third portion of said semiconductor substrate forming second trenches by selectively removing, in cascade, said at least one protective layer, said first conductive layer, said second insulating layer and said semiconductor substrate, for delimiting said second active areas,
filling in said first and second trenches with a filler insulating layer.

10. Process according to claim 1, wherein, before forming said first and second active areas, wells of the P and N type are formed in said first and in said second portion of said semiconductor substrate.

11. Non volatile memory electronic device integrated on a semiconductor substrate which comprises a matrix of non volatile memory cells, said memory cells being organized in rows, called word lines, and columns, called bit lines and an associated circuitry comprising high voltage transistors and low voltage transistors, said non volatile memory cells, said high voltage transistors and low voltage transistors being integrated in respective active areas delimited from each other by self-aligned insulation structures STI, the device comprising:
gate electrodes of non volatile memory cells comprise at least one first conductive layer, one first insulating layer, one second conductive layer and one third conductive layer and are insulated from said semiconductor substrate by means of a second insulating layer,
gate electrodes of high voltage transistors comprise said at least one first conductive layer whereon said third polysilicon layer is overlapped and are insulated from said semiconductor substrate by means of a third insulating layer of greater thickness than said second insulating layer,
gate electrodes of low voltage transistors comprise said second conductive layer whereon said third conductive layer is overlapped and are insulated from said semiconductor substrate by means of a fourth insulating layer.

12. Device according to claim 11, wherein said second conductive layer has a thickness equal to that of said at least one first conductive layer.

13. Device according to claim 11, wherein said fourth insulating layer has a lower thickness than said second insulating layer.

14. Device according to claim 11, wherein said at least one first conductive layer comprises a first conductive layer and a fourth conductive layer.

15. Device according to claim 14, wherein said second conductive layer has a thickness equal to the sum of the thicknesses of said first and fourth conductive layers.

16. Device according to claim 11, wherein gate electrodes of transistors with channel N have a doping of N type and gate electrodes of transistors with channel P have a doping of the P type.

17. Device according to claim 11, wherein said conductive layers are of polysilicon.

18. Device according to claim 11, wherein said insulating layers are of silicon oxide.

19. Device according to claim 14, wherein said fourth conductive layer is of doped polysilicon.

20. An integrated circuit, comprising:
a nonvolatile memory cell including a tunnel insulator of a first thickness and a floating gate disposed on the tunnel insulator;
a first transistor having a first gate insulator of a second thickness and a first gate disposed on the first gate insulator, the second thickness being different than the first thickness; and
a second transistor having a second gate insulator of a third thickness and a second gate disposed on the second gate insulator, the third thickness being different from the first and second thicknesses.

21. The integrated circuit of claim 20 wherein:
the third thickness is less than the first and second thicknesses; and
the first thickness is less than the second thickness.

22. The integrated circuit of claim 20, further comprising:
a substrate over which the floating gate, first gate, and second gate are disposed; and
wherein the first and second gates have approximately a same height above the substrate.

23. The integrated circuit of claim 20, further comprising:
a substrate;
a well of a conductivity type disposed in the substrate; and
wherein the second gate is disposed over the well and has the conductivity type.

24. The integrated circuit of claim 20 wherein:
the floating gate comprises two semiconductor layers;
the first gate comprises three semiconductor layers; and
the second gate comprises two semiconductor layers.

25. The integrated circuit of claim 20, further comprising:
wherein the floating gate comprises two semiconductor layers;
wherein the first gate comprises three semiconductor layers;
wherein the second gate comprises two semiconductor layers; and
a control gate disposed over the floating gate and comprising two semiconductor layers.

26. A method, comprising:
forming over a first portion of a substrate a first gate insulator having a first thickness;
forming over second and third portions of the substrate a second gate insulator having a second thickness;
forming over the first, second, and third portions of the substrate a first conductive layer;
forming over the first conductive layer a third gate insulator;
removing the second gate insulator, the first conductive layer, and the third gate insulator from over the third portion of the substrate;
forming over the third portion of the substrate a fourth gate insulator having a third thickness;
forming over the first, second, and third portions of the substrate a second conductive layer;
removing the second conductive layer and the third gate insulator from over the second portion of the substrate;
forming a third conductive layer over the first, second, and third portions of the substrate;
forming over the first portion of the substrate a floating gate from the first conductive layer;
forming over the second portion of the substrate a first gate from the first and third conductive layers; and
forming over the third portion of the substrate a second gate from the second and third conductive layers.

27. The method of claim 26, wherein the first thickness is greater than the third thickness and less than the second thickness.

28. The method of claim 26 wherein forming the first conductive layer comprises:
forming over the first, second, and third portions of the substrate a fourth conductive layer; and
forming over the fourth conductive layer the first conductive layer.

29. The method of claim 26 wherein forming the first conductive layer comprises:
forming over the first, second, and third portions of the substrate a fourth conductive layer;
forming over the fourth conductive layer the first conductive layer; and
doping the first conductive layer with a first dopant type.

30. The method of claim 26 wherein forming the first conductive layer comprises:
forming over the first, second, and third portions of the substrate a fourth conductive layer;
forming over the fourth conductive layer the first conductive layer; and
doping the first conductive layer with a first dopant type.

31. The method of claim 26, further comprising:
forming a first well of a first conductivity type in the third portion of the substrate;
forming a second well of a second conductivity type in the third portion of the substrate;
wherein forming the second gate comprises forming the second gate over the first well;
forming over the second well a third gate from the second and third conductive layers;
causing the second gate to have the first conductivity type; and
causing the third gate to have the second conductivity type.

32. The method of claim 26, further comprising forming over the floating gate a control gate from the second and third conductive layers.

33. A system, comprising:
a first integrated circuit, comprising,
a nonvolatile memory cell including a tunnel insulator of a first thickness and a floating gate disposed on the tunnel insulator,
a first transistor having a first gate insulator of a second thickness and a first gate disposed on the first gate insulator, the second thickness being different than the first thickness, and
a second transistor having a second gate insulator of a third thickness and a second gate disposed on the second gate insulator, the third thickness being different from the first and second thicknesses; and
a second integrated circuit coupled to the first integrated circuit.

34. The system of claim 33 wherein the first and second integrated circuits are disposed on a same die.

35. The system of claim 33 wherein the first and second integrated circuits are disposed on respective dies.

36. The system of claim 33 wherein the second integrated circuit comprises a controller.
